(19) United States
(12) Patent Application Publication
(10) Pub. No.: US 2012/0122319 A1
(43) Pub. Date: May 17, 2012

(54) COATING METHOD FOR COATING REACTION TUBE PRIOR TO FILM FORMING PROCESS

(76) Inventor: Hironobu SHIMIZU, Toyama-shi (JP)

(21) Appl. No.: 13/316,781

(22) Filed: Dec. 12, 2011

Related U.S. Application Data
(63) Continuation-in-part of application No. 12/212,306, filed on Sep. 17, 2008, now abandoned.

(30) Foreign Application Priority Data
Sep. 19, 2007 (JP) 2007-242630

(51) Int. Cl. H01L 21/31; C23C 16/50

(52) U.S. Cl. 438/765; 427/569; 257/E21.24

(57) ABSTRACT

Contamination of a substrate can be prevented or suppressed. A substrate processing apparatus includes a reaction tube having an inner space divided by a barrier wall into a film forming space and a plasma generating space. When a desired film is formed on a substrate placed inside the reaction tube, first and second processing gases are supplied to the reaction tube through nozzles. On the other hand, when a part of the reaction tube constituting the plasma generating space is coated with a film, second and third processing gases are supplied to the plasma generating space through the nozzle.

### CROSS-REFERENCE TO RELATED PATENT APPLICATIONS

The present application is a Continuation-in-Part application of application Ser. No. 12/212,306, filed on Sep. 17, 2008; which claims priority under 35 U.S.C. §119 of Japanese Patent Application No. 2007-242630, filed on Sep. 19, 2007, in the Japanese Patent Office, the subject matter of which is also incorporated by reference herein.

### BACKGROUND OF THE INVENTION

1. Field of the Invention

The present invention relates to a substrate processing apparatus and a coating method of the substrate processing apparatus, and more particularly, to technology for preventing or suppressing penetration of a contaminant into a reaction tube in which a substrate is accommodated.

2. Description of the Prior Art

In a substrate processing apparatus which performs substrate processing inside a reaction tube in which a substrate is accommodated, although different kinds of processing gases may be supplied to the inside of the reaction tube, the inside of the reaction tube is divided into a film forming space and a plasma generating space, and one of the processing gases is directly supplied to the film forming space, and another is plasma-excited in the plasma generating space and is then supplied to the film forming space. In this case, as plasma is generated, ions are produced in quartz of the reaction tube, and resulting ionized contaminants penetrate through the reaction tube into the film forming space to contaminate the substrate. For this reason, the inner wall of the reaction tube is coated with a film beforehand, so as to suppress penetration of ionized contaminants into the film forming space (for example, refer to Patent Document 1 below)

[Patent Document 1]

International Publication No. 2004/044970 Pamphlet.

However, since the inner space of the reaction tube is generally divided into the film forming space and the plasma generating space by a barrier wall, although the inner wall of the reaction tube is coated with a film, a part of the reaction tube constituting the film forming space may be mainly coated, and a part of the reaction tube constituting the plasma generating space may be insufficiently coated. In this case, when plasma is generated in a film forming process, contaminants such as ions may penetrate into the plasma generating space through the part of the reaction tube constituting the plasma generating space, and further into the film forming space to contaminate the substrate.

### SUMMARY OF THE INVENTION

An object of the present invention is to provide a substrate processing apparatus and a coating method of the substrate processing apparatus which can prevent or restrain contaminants from penetrating a reaction tube and contaminating a substrate.

According to an aspect of the present invention, there is provided a coating method for coating a reaction tube having a film forming space where a desired film is formed on a substrate accommodated therein and a plasma generating space where a plasma is generated, the coating method comprising: supplying a first processing gas into the plasma generating space and exhausting at least a portion of the first processing gas from the plasma generating space without loading the substrate into the film forming space; and supplying a second processing gas into the plasma generating space to coat at least the plasma generating space with the desired film and exhausting at least a portion of the second processing gas from the plasma generating space without loading the substrate into the film forming space.

According to another aspect of the present invention, there is provided a coating method performed in a substrate processing apparatus comprising a reaction tube having a film forming space where a desired film is formed on a substrate accommodated therein and a plasma generating space where a plasma is generated; a gas supply unit configured to supply a first processing gas and a second processing gas into the reaction tube; at least one electrode disposed in the plasma generating space and connected to a high-frequency power supply unit; and an exhaust unit configured to exhaust an inside atmosphere of the reaction tube, the coating method comprising: supplying the first processing gas into the plasma generating space by the gas supply unit without loading the substrate into the film forming space; exhausting the inside atmosphere of the reaction tube by the exhaust unit; supplying the second processing gas into the plasma generating space by the gas supply unit without loading the substrate into the film forming space; and exhausting the inside atmosphere of the reaction tube by the exhaust unit, wherein at least the plasma generating space of the reaction tube is coated with the desired film.

According to another aspect of the present invention, there is provided a method for manufacturing a semiconductor device using a reaction tube coating having a film forming space where a desired film is formed on a substrate accommodated therein and a plasma generating space where a plasma is generated, the coating method comprising: supplying a first processing gas into the plasma generating space and exhausting at least a portion of the first processing gas from the plasma generating space without loading the substrate into the film forming space; supplying a second processing gas into the plasma generating space to coat at least the plasma generating space with the desired film and exhausting at least a portion of the second processing gas from the plasma generating space without loading the substrate into the film forming space; and forming the desired film is on the substrate in the film forming space with the substrate loaded therein after coating the at least the plasma generating space with the desired film.

### BRIEF DESCRIPTION OF THE DRAWINGS

FIG. 1 is a schematic perspective view illustrating a substrate processing apparatus, relevant to a preferred embodiment (a first embodiment) of the present invention.

FIG. 2 is a schematic view illustrating a vertical type processing furnace and accompanying members of the vertical type processing furnace used in the preferred embodiment (the first embodiment) of the present invention, and particularly illustrating a longitudinal section of the vertical type furnace.

FIG. 3 is a schematic view illustrating the vertical type processing furnace and a nozzle used in the preferred embodiment (the first embodiment) of the present invention, and particularly illustrating a cross section of the processing furnace.

FIG. 4 is a schematic view illustrating comparative examples of the processing furnace and the nozzle of FIG. 3.

FIG. 5 is a schematic view illustrating a vertical type processing furnace and a nozzle used in another preferred embodiment (a second embodiment) of the present invention, and particularly illustrating a cross section of the processing furnace.

FIG. 6 is a schematic view illustrating a vertical type processing furnace and a nozzle used in another preferred embodiment (a third embodiment) of the present invention, and particularly illustrating a cross section of the processing furnace.

FIG. 7 is a flow diagram illustrating a coating method in accordance with an embodiment of the present invention.

### DETAILED DESCRIPTION OF THE PREFERRED EMBODIMENTS

Preferable embodiments of the present invention will be described hereinafter with reference to the attached drawings.

### First Embodiment

In the current embodiment, the substrate processing apparatus of the present invention is configured as an example of a semiconductor manufacturing apparatus used for manufacturing semiconductor device integrated circuits (ICs). In the following description, the use of a vertical apparatus, which performs a process such as heat treatment on a substrate, will be described as an example of a substrate processing apparatus.

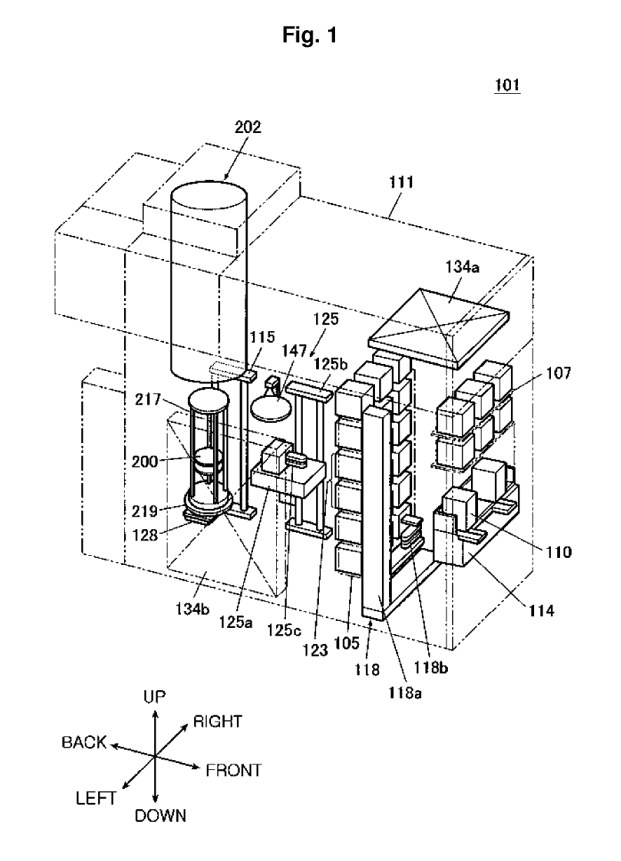

As shown in FIG. 1, in a substrate processing apparatus 101, a cassette 110 is used to store a substrate such as a wafer 200, and the wafer 200 is made of a material such as silicon. The substrate processing apparatus 101 is provided with a housing 111, in which a cassette stage 114 is installed. The cassette 110 is designed to be carried onto the cassette stage 114, or carried away from the cassette stage 114, by an in-plant carrying unit (not shown).

The cassette stage 114 is installed so that the wafer 200 maintains a vertical position inside the cassette 110, and a wafer carrying-in and carrying-out opening of the cassette 110 faces upward, by the in-plant carrying unit. The cassette stage 114 is configured so that the cassette 110 is rotated 90° counterclockwise in a longitudinal direction to the backward of the housing 111, and the wafer 200 inside the cassette 110 takes a horizontal position, and the wafer carrying-in and carrying-out opening of the cassette 110 faces the backward of the housing 111.

Near the center portion of the housing 111 in a front-to-back direction, a cassette shelf 105 is installed. The cassette shelf 105 is configured so that a plurality of the cassettes 110 are stored in a plurality of stages and a plurality of rows. At the cassette shelf 105, a transfer shelf 123 is installed to store the cassettes 110, which are carrying objects of a wafer transfer mechanism 125.

At the upside of the cassette stage 114, a standby cassette shelf 107 is installed, and configured to store standby cassettes 110.

Between the cassette stage 114 and the cassette shelf 105, a cassette carrying unit 118 is installed. The cassette carrying unit 118 is configured by a cassette elevator 118a, which is capable of moving the cassette 110 upward and downward while holding the cassette 110, and a cassette carrying mechanism 118b. The cassette carrying unit 118 is designed to carry the cassette 110 in and out of the cassette stage 114, the cassette shelf 105 and the standby cassette shelf 107, by continuous motions of the cassette elevator 118a and the cassette carrying mechanism 118b.

At the backside of the cassette shelf 105, the wafer transfer mechanism 125 is installed. The wafer transfer mechanism 125 is configured by a wafer transfer unit 125a that is capable of rotating or linearly moving the wafer 200 in a horizontal direction, and a wafer transfer unit elevator 125b for moving the wafer transfer unit 125a upward and downward. At the wafer transfer unit 125a, tweezers 125c are installed to pick up the wafer 200. The wafer transfer mechanism 125 is configured so as to pick up the wafer 200 by the tweezers 125c, and charge the wafer 200 into a boat 217, or discharge the wafer 200 from the boat 217, by continuous motions of the wafer transfer unit 125a and the wafer transfer unit elevator 125b.

At the upside of the rear part of the housing 111, a processing furnace 202 is installed to perform heat treatment on the wafer 200, and the lower end portion of the processing furnace 202 is configured so as to be opened and closed by a furnace port shutter 147.

At the downside of the processing furnace 202, a boat elevator 115 is installed to move the boat 217 upward to and downward from the processing furnace 202. An arm 128 is connected to an elevating table of the boat elevator 115, and a seal cap 219 is horizontally attached to the arm 128. The seal cap 219 supports the boat 217 vertically, and is configured so as to be able to block the lower end portion of the processing furnace 202.

The boat 217 is provided with a plurality of holding members, and is configured so as to hold a plurality of wafers 200 (for example, about fifty to one hundred fifty wafers) each horizontally, in a state that the centers thereof are aligned and arranged in a vertical direction.

At the upside of the cassette shelf 105, a cleaning unit 134a is installed to supply clean air as purified atmosphere. The cleaning unit 134a is configured by a supply fan and a dust filter, so as to supply clean air to the inside of the housing 111.

At the left side end portion of the housing 111, another cleaning unit 134b is installed to supply clean air. The cleaning unit 134b is also configured by a supply fan and a dust filter, so as to supply clean air to the surrounding area of the wafer transfer unit 125a, the boat 217, or the like. After flowing around the wafer transfer unit 125a, the boat 217 or the like, the clean air is exhausted to the outside of the housing 111.

Next, a main operation of the substrate processing apparatus 101 will be described.

When the cassette 110 is carried onto the cassette stage 114 by the in-plant carrying unit (not shown), the cassette 110 is placed in a state that the wafer 200 inside the cassette 110 is held in a vertical position, and the wafer carrying-in and carrying-out opening of the cassette 110 faces upward. Thereafter, the cassette 110 is rotated counterclockwise by 90° in a longitudinal direction toward the backward of the housing 111 by the cassette stage 114 so that the wafer 200 in side the cassette 110 takes a horizontal position, and the wafer carrying-in and carrying-out opening of the cassette 110 faces the backward of the housing 111.

Then, the cassette 110 is automatically carried and placed by the cassette carrying unit 118 to a specified shelf position of the cassette shelf 105 or the standby cassette shelf 107 so as to be temporarily stored, and then transferred to the transfer shelf 123 from the cassette shelf 105 or the standby cassette shelf 107, by the cassette carrying unit 118, or directly transferred to the transfer shelf 123.

After the cassette 110 is transferred to the transfer shelf 123, the wafer 200 is picked up from the cassette 110 through the wafer carrying-in and carrying-out opening and is charged into the boat 217 by the tweezers 125c of the wafer transfer unit 125a. After delivering the wafer 200 to the boat 217, the wafer transfer unit 125a returns to the cassette 110, and charges the next wafer 200 into the boat 217.

After a predetermined number of wafers 200 are charged into the boat 217, the lower end portion of the processing furnace 202 closed by the furnace port shutter 147 is opened by moving the furnace shutter 147. Subsequently, the boat 217 holding a group of wafers 200 is loaded into the processing furnace 202 by an ascending motion of the boat elevator 115, and the lower end portion of the processing furnace 202 is closed by the seal cap 219.

After the loading, predetermined heat treatment is performed on the wafers 200 inside the processing furnace 202. Thereafter, the wafers 200 and the cassette 110 are carried out to the outside of the housing 111 in a reverse sequence of the above.

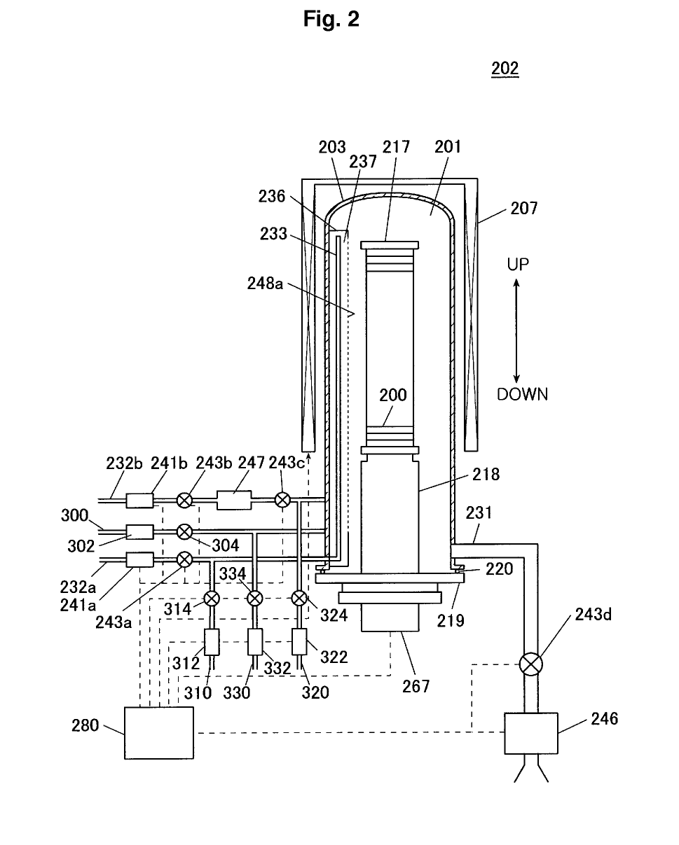

As shown in FIG. 2, at the processing furnace 202, a heater 207 is installed as a heating unit. The heater 207 includes an insulating material and a heating wire, and configured so that the heating wire is wound around the insulating material (this configuration is not shown). Inside the heater 207, a reaction tube 203 is installed, which is capable of storing the wafer 200, which is an example of a substrate. The reaction tube 203 is made of quartz. A lower end opening of the reaction tube 203 is tightly sealed by a cap body such as the seal cap 219 with an O-ring being disposed between the reaction tube 203 and the seal cap 219. In the current embodiment, a processing chamber 201 is formed by at least the reaction tube 203 and the seal cap 219.

At the seal cap 219, the boat 217 that is a substrate holding member is installed with a boat support stand 218 in-between. The boat support stand 218 is a holding body which is used to hold the boat 217. The boat 217 is inserted in the processing chamber 201. At the boat 217, a plurality of wafers 200 to be batch processed are held in a horizontal position and are piled in multiple stages in an up-and-down direction of FIG. 2. The heater 207 heats the wafers 200 placed inside the processing chamber 201 to a predetermined temperature.

To a lower portion of the processing chamber 201, three gas supply pipes 232a, 232b and 300 are connected to supply a plurality of gases.

At the gas supply pipe 232a, a mass flow controller 241a which is a flow rate control unit, and a valve 243a which is an opening-closing valve are installed. A processing gas such as NH₃ gas is introduced into the gas supply pipe 232a and is supplied to the processing chamber 201 through a buffer chamber 237 (described later) formed in the reaction tube 203.

At the gas supply pipe 232b, a mass flow controller 241b which is a flow rate control unit, a valve 243b which is an opening-closing valve, a gas storage 247, and a valve 243c which is an opening-closing valve are installed. A processing gas such as dichlorosilane (SiH₂Cl₂, DCS) is introduced into the gas supply pipe 232b and is supplied to the processing chamber 201 through a gas supply unit 249 (described later).

At the gas supply pipe 300, a mass flow controller 302 which is a flow rate control unit, and a valve 304 which is an opening-closing valve are installed. A processing gas such as DCS gas is introduced into the gas supply pipe 300 and is supplied to the processing chamber 201 through the buffer chamber 237 (described later) formed in the reaction tube 203.

To the above-described gas supply pipes 232a, 232b and 300, gas supply pipes 310, 320 and 330 are connected, respectively. At the gas supply pipes 310, 320 and 330, mass flow controllers 312, 322 and 332 which are flow rate control units, and valves 314, 324 and 334 which are opening-closing valves are installed, respectively. Inert gas such as N₂ gas is introduced into the gas supply pipes 310, 320 and 330.

To the processing chamber 201, an end of a gas exhaust pipe 231 is connected so as to exhaust the inside atmosphere of the processing chamber 201. A valve 243d is installed at the gas exhaust pipe 231. At the other end of the gas exhaust pipe 231, a vacuum pump 246, which is an exhaust unit, is connected so as to evacuate the inside of the processing chamber 201. The valve 243d is an opening-closing valve which is configured to be opened and closed so as to start and stop evacuation of the processing chamber 201, and configured to be adjusted in opening size for pressure controlling.

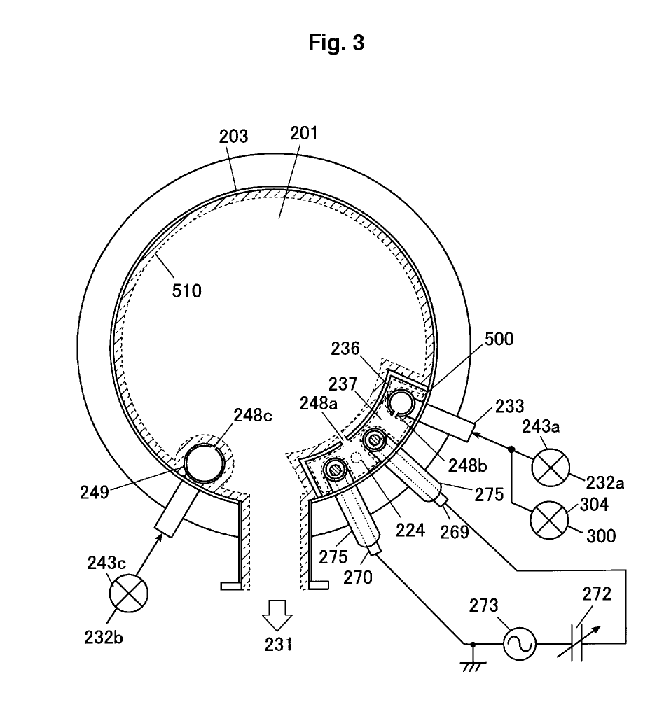

As shown in FIG. 3, at an arc-shaped space between an inner wall of the reaction tube 203 forming the processing chamber 201 and wafers 200, a barrier wall 236 made of quartz is installed. In a state where ends of the barrier wall 236 are in tight contact with the inner wall of the reaction tube 203, the barrier wall 236 extends from the back to the front of the plane of FIG. 3 (the up-and-down direction of FIG. 2). As shown in FIG. 2, upper and lower ends of the barrier wall 236 are in tight contact with the inner wall of the reaction tube 203, and inside the barrier wall 236, the buffer chamber 237 is formed and is surround by the barrier wall 236 and a part of the reaction tube 203. That is, the inner space of the reaction tube 203 is divided by the barrier wall 236.

At a portion of the barrier wall 236 facing the wafers 200, a plurality of gas supply holes 248a are formed. The gas supply holes 248a are opened toward the center of the reaction tube 203. The gas supply holes 248a have the same open area and are formed at the same pitch from the downside to the upside of FIG. 2.

A nozzle 233 is installed at an end of the buffer chamber 237 opposite to an end where the gas supply holes 248a are formed. The gas supply pipe 232a is connected to the nozzle 233, and the gas supply pipe 300 is connected to a middle portion of the gas supply pipe 232a. The nozzle 233 extends from the downside to the upside of the reaction tube 203 in the up-and-down direction of FIG. 2.

At the nozzle 233, a plurality of gas supply holes 248b are formed. The gas supply holes 248b are designed such that when the pressure difference between the buffer chamber 237 and the processing chamber 201 is small, the gas supply holes 248b have the same open area and are formed at the same pitch from the upstream side to the downstream side of gas, and when the pressure difference is large, the open area of the gas supply holes 248b increases or the pitch of the gas supply holes 248b decreases from the upstream side to the downstream side.

In the current embodiment, the gas supply holes 248b gradually increase in size from the upstream side to the downstream side. Owing to this configuration, when gas is injected to the buffer chamber 237 through the gas supply holes 248b, the flow rate of the gas can be approximately constant although the velocity of the gas varies. Thereafter, the gas injected inside the buffer chamber 237 decreases in molecule velocity difference and is injected to the processing chamber 201 through the gas supply holes 248a. When the gas injected through the gas supply holes 248b is further injected through the gas supply holes 248a, the flow rate and velocity of the gas can be constant.

At the buffer chamber 237, a pair of rod-shaped electrodes 269 and 270 having a slender and long shape is installed. The rod-shaped electrodes 269 and 270 extend in the up-and-down direction of FIG. 2 and are enclosed and protected by electrode protection tubes 275. One of the rod-shaped electrodes 269 and 270 is connected to a high-frequency power source 273 through a matching device 272, and the other is grounded to a reference potential. When high-frequency power is supplied to the rod-shaped electrodes 269 and 270, plasma is generated in a plasma generating space 224 between the rod-shaped electrodes 269 and 270. In the current embodiment, a high-frequency power supply unit is formed by at least the matching device 272 and the high-frequency power source 273.

The electrode protection tubes 275 are configured so that the respective rod-shaped electrodes 269 and 270 can be inserted into the buffer chamber 237 in a state that the rod-shaped electrodes 269 and 270 are isolated from the atmosphere of the buffer chamber 237. If the atmosphere in the electrode protection tubes 275 is the same as outside air (atmosphere), the respective rod-shaped electrodes 269 and 270 inserted in the electrode protection tubes 275 are oxidized by heat of the heater 207. Hence, in the current embodiment, to prevent oxidation of the rod-shaped electrodes 269 and 270, an inert gas purge mechanism (not shown) is installed, and the inside areas of the electrode protection tubes 275 are charged or purged with inert gas such as nitrogen, thereby maintaining oxygen concentration at a sufficiently low level.

As shown in FIG. 3, inside the reaction tube 203, the gas supply unit 249 (a nozzle) is installed. The gas supply pipe 232b is connected to the gas supply unit 249. The gas supply unit 249 is installed at a position apart from the gas supply hole 248a to form an angle of about 60° about the center of the reaction tube 203. When a plurality of gases are supplied to the wafers 200 one after another in a film forming process by an atomic layer deposition (ALD) method, the gas supply unit 249 shares the task of supplying the plurality of gases with the buffer chamber 237.

At the gas supply unit 249, a plurality of gas supply holes 248c are formed at positions facing the wafers 200. The gas supply holes 248c extend in the up-and-down direction of FIG. 2.

Preferably, the gas supply holes 248c are designed such that when the pressure difference between the gas supply unit 249 and the processing chamber 201 is small, the gas supply holes 248c have the same open area and are formed at the same pitch from the upstream side to the downstream side of gas, and when the pressure difference is large, the open area of the gas supply holes 248c increases or the pitch of the gas supply holes 248c decreases from the upstream side to the downstream side. In the current embodiment, the open area of the gas supply holes 248c increases gradually from the upstream side to the downstream side.

As shown in FIG. 2, at a center portion inside the reaction tube 203, the boat 217, in which a plurality of the wafers 200 are placed in multiple stages at the same intervals, is installed. The boat 217 is configured so that the boat 217 is loaded into and unloaded from the reaction tube 203 by the boat elevator 115 (refer to FIG. 1). Under the boat 217, a boat rotating mechanism 267 is installed to rotate the boat 217 and thus to improve processing uniformity. By rotating the boat rotating mechanism 267, the boat 217 held on the boat support stand 218 can be rotated.

A controller 280, which is a control unit, is connected to elements such as the mass flow controllers 241a, 241b, 302, 312, 322 and 332, the valves 243a, 243b, 243c, 243d, 304, 314, 324 and 334, the heater 207, the vacuum pump 246, the boat rotating mechanism 267, the boat elevator 115, the high-frequency power source 273, and the matching device 272.

In the current embodiment, the controller 280 controls operations such as flow rate adjusting operations of the mass flow controllers 241a, 241b, 302, 312, 322 and 332; opening and closing operations of the valves 243a, 243b, 243c, 304, 314, 324 and 334; opening, closing, and pressure adjusting operations of the valve 243d; a temperature adjusting operation of the heater 207; start and stop operations of the vacuum pump 246; a rotation speed adjusting operation of the boat rotating mechanism 267; an elevating operation of the boat elevator 115; a power supply operation of the high-frequency power source 273; and an impedance adjusting operation of the matching device 272.

Next, as an example of forming a film with an ALD method, forming a Si₃N₄ film using DCS gas and NH₃ gas, which is a semiconductor device manufacturing process, will be explained.

In the ALD method which is a kind of chemical vapor deposition (CVD) method, processing gases, which are two (or more) kinds of materials used in film formation, are sequentially supplied to a substrate one after another under predetermined film formation conditions (temperature, time, etc.), and the processing gases are adsorbed on the substrate on an atomic layer basis to form a film by a surface reaction.

The use of a chemical reaction is such that, for example, when a silicon nitride (Si₃N₄) film is formed by the ALD method, high-quality film growth at a low temperature of 300° C. to 600° C. is possible by using DCS and ammonia (NH₃). In addition, the gas supply is carried out in a way of supplying a plurality of processing gases one after another. Therefore, the thickness of the film can be controlled by adjusting the number of processing gas supply cycles (for example, if the film forming rate is 1 Å/cycle and it is intended to form a 20-Å film, the process is repeated 20 cycles).

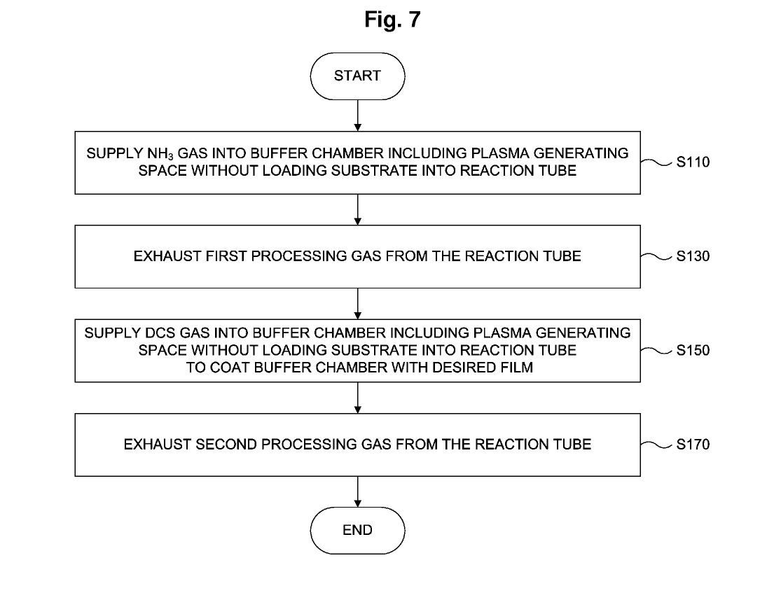

Prior to a film forming process as being described later, a coating process will be described with reference to FIGS. 1 through 3 and FIG. 7. In the following description, the coating process is performed in a state where a wafer 200 is not placed in the reaction tube 203.

[Coating Process]

In a state where NH₃ gas is introduced into the gas supply pipe 232a, the valves 243a and 243d are opened. While controlling the flow rate of the NH₃ gas using the mass flow controller 241a, the NH₃ gas is injected to the buffer chamber 237 including the plasma generating space 224 through the gas supply holes 248b of the nozzle 233 (S110). While supplying the NH₃ gas through the gas supply holes 248a, the NH₃ gas is exhausted through the gas exhaust pipe 231(S130). At this time, high-frequency power is not supplied to the rod-shaped electrodes 269 and 270 so as not to excite the NH₃ gas into a plasma state. In addition, the heater 207 is controlled to keep the temperature of the buffer chamber 237 in the range of 580° C. to 630° C. After a predetermined time, the valve 243a is closed to cut off the supply of the NH₃ gas, and simultaneously, the valve 314 is opened in a state where N₂ gas is introduced into the gas supply pipe 310 so as to purge the NH₃ gas from the processing chamber 201 and the like by using the N₂ gas.

Thereafter, in a state where DCS gas is introduced into the gas supply pipe 300, the valve 304 is opened. While controlling the flow rate of the DCS gas using the mass flow controller 302, the DCS gas is injected to the buffer chamber 237 including the plasma generating space 224 through the gas supply holes 248b of the nozzle 233(S150). While supplying the DCS gas through the gas supply holes 248a, the DCS gas is exhausted through the gas exhaust pipe 231(S170). As a result, a Si₃N₄ film 500 is formed mainly on a part of the inner wall of the reaction tube 203 that constitutes the buffer chamber 237, and the inner wall of the barrier wall 236. Furthermore, in the process, since the NH₃ gas and the DCS gas are also supplied to the processing chamber 201 through the barrier wall 236 and the gas supply holes 248a, a Si₃N₄ film 510 is also formed on the outer wall of the barrier wall 236 and a part of the inner wall of the reaction tube 203 that constitutes a film forming space, along with the formation of the Si₃N₄ film 500.

After a predetermined time, the valve 304 is closed to cut off the supply of the DCS gas, and simultaneously, the valve 334 is opened in a state where N₂ gas is introduced into the gas supply pipe 330 to purge the DCS gas from the processing chamber 201 and other places by using the N₂ gas.

This process is repeated a plurality of times in order to coat mainly the inside of the buffer chamber 237 with the Si₃N₄ film 500 to a predetermined thickness. In the case where 50-W high-frequency power is supplied to the electrodes 269 and 270 in the film forming process as described later, the coating process is continued until the thickness of the Si₃N₄ film 500 reaches 150 Å or more. If the thickness of the Si₃N₄ film 500 is equal to or greater than 150 Å, the buffer chamber 237 can be protected from penetration of sodium (Na) which contaminates the wafer 200, at a penetration rate of 1×10¹⁰ atoms/cm² or less, even though 50-W high-frequency power is supplied to the electrodes 269 and 270. It is considered that the penetration of the contaminant, Na, increases in proportion to high-frequency power (discharge power) supplied to the electrodes 269 and 270.

In the above-described coating process, instead of DCS gas, the same kind of gas (Si-containing gas) may be used.

In the above-described coating process, along with the coating of the inside of the buffer chamber 237 with the Si₃N₄ film 500, the outside of the buffer chamber 237 is simultaneously coated with the Si₃N₄ film 510; however, the outside of the buffer chamber 237 may be coated with the Si₃N₄ film 510, separately from the process of coating the inside of the buffer chamber 237 with the Si₃N₄ film 500.

In the case where the outside of the buffer chamber 237 is coated, the following process is performed.

In a state where NH₃ gas is introduced into the gas supply pipe 232a, the valves 243a and 243d are opened. While controlling the flow rate of the NH₃ gas using the mass flow controller 241a, the NH₃ gas is injected to the buffer chamber 237 through the gas supply holes 248b of the nozzle 233, and while supplying the NH₃ gas to the processing chamber 201 through the gas supply holes 248a, the NH₃ gas is exhausted through the gas exhaust pipe 231. At this time, high-frequency power is not supplied to the rod-shaped electrodes 269 and 270 so as not to excite the NH₃ gas into a plasma state. In addition, the heater 207 is controlled to keep the temperature of the buffer chamber 237 in the range of 580° C. to 630° C. After a predetermined time, the valve 243a is closed to cut off the supply of the NH₃ gas, and simultaneously, the valve 314 is opened in a state where N₂ gas is introduced into the gas supply pipe 310 so as to purge the NH₃ gas from the processing chamber 201 and other places by using the N₂ gas.

Thereafter, in a state where DCS gas is introduced into the gas supply pipe 232b, the valves 243b and 243c are opened. While controlling the flow rate of the DCS gas using the mass flow controller 241b, the DCS gas is injected to the processing chamber 201 through the gas supply holes 248c of the gas supply unit 249, and while supplying the DCS gas to the processing chamber 201, the DCS gas is exhausted through the gas exhaust pipe 231. As a result, a Si₃N₄ film 510 is formed mainly on the inner wall of the reaction tube 203 and the outer wall of the barrier wall 236. After a predetermined time, the valves 243b and 243c are closed to cut off the supply of the DCS gas, and simultaneously, the valve 324 is opened in a state where N₂ gas is introduced into the gas supply pipe 320 so as to purge the DCS gas from the processing chamber 201 and other places by using the N₂ gas.

By repeating this process a plurality of times, the Si₃N₄ film 510 having a predetermined thickness is formed mainly on the outside of the buffer chamber 237 at the inside of the processing chamber 201.

[Film Forming Process]

Next, a film forming process is performed on the wafer 200. The wafer 200 to be processed is charged in the boat 217 and is loaded into the processing chamber 201. After loading, the following four steps are sequentially performed.

(Step 1)

In the step 1, NH₃ gas necessary for plasma excitation, and DCS gas unnecessary for plasma excitation are allowed to flow in sequence. First, in a state where NH₃ gas is introduced into the gas supply pipe 232a, the valve 243a of the gas supply pipe 232a and the valve 243d of the gas exhaust pipe 231 are opened at the same time. While controlling the flow rate of the NH₃ gas using the mass flow controller 241a, the NH₃ gas is injected into the buffer chamber 237 through the gas supply holes 248b of the nozzle 233. In this state, high-frequency power is supplied to the rod-shaped electrodes 269 and 270 through the matching device 272 in order to excite the NH₃ gas into a plasma state, and while supplying the excited NH₃ gas to the processing chamber 201 as an activated species, the NH₃ gas is exhausted through the gas exhaust pipe 231.

When the NH₃ gas is plasma-excited and allowed to flow as an activated species, the valve 243d is properly adjusted to keep the pressure inside the processing chamber 201 in the range of 10 Pa to 100 Pa, for example, 50 Pa. By controlling the mass flow controller 241a, the NH₃ gas is supplied at a rate of 1 slm to 10 slm, for example, 5 slm. The wafer 200 is exposed to the activated species produced by plasma-exciting the NH₃ gas for 2 seconds to 120 seconds. At this time, the heater 207 is controlled to keep the temperature of the wafer 200 in the range of 300° C. to 600° C. (preferably, 450° to 550° C.), for example, at 530° C. Since NH₃ gas has a high reaction temperature, the NH₃ gas does not react in the above-mentioned temperature range. In the current embodiment, since the NH₃ gas is plasma-excited and allowed to flow as an activated species, the process is performed while maintaining the wafer 200 in a low temperature range.

While the NH₃ gas is plasma-excited and supplied as an activated species, the upstream-side valve 243b of the gas supply pipe 232b is opened, and the downstream-side valve 243c of the gas supply pipe 232b is closed, so as to allow a flow of DCS gas. Then, the DCS gas is stored in the gas storage 247 installed between the valves 243b and 243c. At this time, gas flowing in the processing chamber 201 is the activated species produced by plasma-exciting NH₃ gas, and the DCS gas does not exist in the processing chamber 201. Although the NH₃ gas does not cause a gas-phase reaction, the activated species produced by plasma exciting the NH₃ gas undergoes a surface reaction (chemical adsorption) with a surface such as a base layer of the wafer 200.

(Step 2)

In the step 2, the valve 243a of the gas supply pipe 232a is closed to cut off the supply of the NH₃ gas, but the DCS gas is allowed to flow continuously to continue supply of the DCS gas to the gas storage 247. When a predetermined amount of the DCS gas is filled in the gas storage 247 at a predetermined pressure, the upstream-side valve 243b is closed so as to hermetically close the gas storage 247 containing the DCS gas. In addition, the valve 243d of the gas exhaust pipe 231 is kept in an opened state so as to exhaust the atmosphere of the processing chamber 201 to a pressure of 20 Pa or lower by using the vacuum pump 246, and thereby to remove the remaining NH₃ gas from the processing chamber 201.

At this time, the valve 314 can be opened in a state where N₂ gas is introduced into the gas supply pipe 310 so as to supply the N₂ gas to the processing chamber 201, which increases the efficiency of removing the remaining NH₃ gas from the processing chamber 201. Inside the gas storage 247, the DCS gas is stored at a pressure of 20000 Pa or higher. It is configured so that the conductance between the gas storage 247 and the processing chamber 201 is equal to or higher than 1.5×10⁻³ m³/s.

For example, when the volume of the reaction tube 203 and the corresponding volume of the gas storage 247 are considered, it is preferable that if the volume of the reaction tube 203 is 100 l, the volume of the gas storage 247 be 100 cc to 300 cc, and in terms of volume ratio, it is preferable that the volume of the gas storage 247 be 1/1000 to 3/1000 the volume of the reaction tube 203.

(Step 3)

In the step 3, after the reaction tube 203 is completely exhausted, the valve 243d of the gas exhaust pipe 231 is closed to stop the exhausting operation. Then, the downstream-side valve 243c of the gas supply pipe 232b is opened. Thus, the DCS contained in the gas storage 247 is supplied to the processing chamber 201 all at once through the gas supply holes 248c of the gas supply unit 249. Since the valve 243d of the gas exhaust pipe 231 is closed, the pressure inside the processing chamber 201 increases steeply up to about 931 Pa (7 Torr). The time for supplying the DCS gas is set to 2 seconds to 4 seconds; exposure time to the increased-pressure atmosphere is set to 2 seconds to 4 seconds; and the total time is set to 6 seconds. At this time, the heater 207 is controlled to maintain the temperature of the wafer 200 in the range of 300° C. to 600° C. (preferably, 450° to 550° C.), for example, at 530° C., like in the case of supplying the NH₃ gas. By supplying the DCS gas, NH₃ adsorbed on the surface of the wafer 200 undergoes a reaction (chemical adsorption) with DCS, and thus a Si₃N₄ film is formed on the wafer 200.

(Step 4)

In the step 4 after the film formation, the valve 243c is closed and the valve 243d is opened so as to evacuate the processing chamber 201 for removing the DCS gas remaining in the processing chamber 201 after the film formation. In addition, at this time, the valve 324 may be opened in a state where N₂ gas is introduced into the gas supply pipe 320 to supply the N₂ gas to the processing chamber 201 for increasing the efficiency of removing the DCS gas which remains in the processing chamber 201 after the film formation. Then, the valve 243b is opened to start supply of DCS gas to the gas storage 247.

The above-described steps 1 to 4 is set as a cycle, and the cycle is repeated a plurality of times to form the Si₃N₄ film on the wafer 200 to a predetermined thickness.

In an ALD apparatus, gas is chemically adsorbed on the surface of a wafer 200. The amount of adsorbed gas is proportional to the pressure of the gas and exposure time. Therefore, to allow a desired amount of gas to be adsorbed in a short time, it is necessary to increase the pressure of the gas rapidly. In this point, according to the current embodiment, DCS gas stored in the gas storage 247 is rapidly supplied after closing the valve 234d so that the pressure of the DCS gas inside the processing chamber 201 can be steeply increased, and a desired amount of gas can be instantaneously adsorbed.

In the current embodiment, since the supply of plasma-excited NH₃ gas as an activated species, which is a necessary step for an ALD method, and exhaustion of the processing chamber 201 are performed during DCS gas being stored in the gas storage 347, a special step is not necessary for storing the DCS gas. In addition, after NH₃ gas is removed from the processing chamber 201 by exhausting the processing chamber 201, DCS gas is allowed to flow so that both gases do not react with each other on the way to the wafer 200. Supplied DCS gas can be effectively reacted only with NH₃ adsorbed on the wafer 200.

In the above-described embodiment, before the film forming process is performed on the wafer 200, the coating process is performed so that a part constituting the buffer chamber 237 of the reaction tube 203 can be especially coated with the Si₃N₄ film 500. Therefore, although plasma is generated in the buffer chamber 237 in the step 1 when a Si₃N₄ film is actually formed on the wafer 200, Na ions which contaminate the wafer 200 can be prevented from penetrating into a region constituting the buffer chamber 237 of the reaction tube 203, and thus, the wafer 200 can be prevented or restrained from being contaminated by contaminants penetrated into the buffer chamber 237.

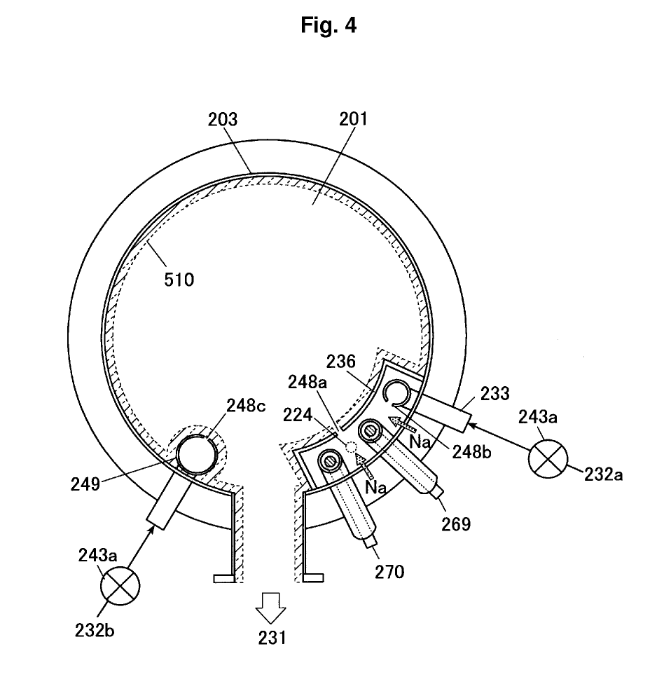

As a comparative example of the substrate processing apparatus 101 relevant to the current embodiment, the structure of FIG. 4 can be considered. In the structure, only a mechanism (e.g., a gas supply pipe 232a connected to a nozzle 233, and the like) for supplying NH₃ gas to a buffer chamber 237 is installed, and a mechanism (e.g., a gas supply pipe 300 connected to the nozzle 233, and the like) for supplying DCS gas to the buffer chamber 237 is not installed. In this case, DCS gas cannot be directly supplied to the buffer chamber 237, and thus a sufficient amount of DCS gas can not be supplied for coating the inside of the buffer chamber 237. Therefore, in a coating process for the comparative example, the inside of the buffer chamber 237 cannot be sufficiently coated basically, and only the outside of the buffer chamber 237 located inside a processing chamber 201 is coated with a Si₃N₄ film 510 to a predetermined thickness.

Hence, in the comparative example, at a film forming process after the coating process, particularly, when NH₃ gas is plasma-excited, Na ions can generate at the outside of a reaction tube 203 and penetrate into the buffer chamber 237 through a part of the reaction tube 203 constituting the buffer chamber 237, and can contaminate a wafer 200 (refer to FIG. 4).

The source of Na is not clear, but elements such as the electrodes 269 and 270, and the insulating material of the heater 207 are currently considered to be the source of Na. The insulating material of the heater 207 is considered to be the source of Na because the insulating material contains a large amount of Na.

Moreover, as described above, in the case where plasma is generated in the buffer chamber 237 during plasma-excitation of NH₃, Na is adsorbed on the outside of the reaction tube 203 and ionized at the inside of quartz during the plasma excitation, and the Na ions penetrate into the inside of the buffer chamber 237. Ionization of Na is not clear; however, the sequence of Na-ion penetration into the buffer chamber 237 is considered as follows.

The radius of Na ions is about 1.6 Å. On the other hand, quartz constituting the reaction tube 203 has structural units of Si—O bonds and a reticular structure called “cristobalite” formed by the structural units connected in a chain shape, and the mesh radius (radius of openings) of the reticular structure is about 1.7 Å. According to the quartz temperature rises, the mesh radius increases (the openings enlarge). As a result, as the temperature of the reaction tube 203 rises, Na ions can freely move through the inside of the quartz material. In this way, Na ions pass through the reaction tube 203, penetrate the buffer chamber 237, and finally attach to the wafer 200.

To cope with this phenomenon, in the current embodiment, the gas supply pipe 300 communicates with the inside of the buffer chamber 237 to perform a coating process for coating the inside of the buffer chamber 237 with the Si₃N₄ film 500, so that Na ions generated at the outside of the reaction tube 203 can be prevented or restrained from passing through the reaction tube 203 and penetrating the buffer chamber 237, and thus contamination of the wafer 200 can be avoided beforehand. That is, according to the current embodiment, it is regarded that since the molecular distance of the Si₃N₄ film 500 is smaller than the ion radius of Na, the Si₃N₄ film 500 prevents or suppresses penetration of Na ions into the buffer chamber 237.

### Second Embodiment

The second embodiment is the same as the first embodiment in all aspects, except for those described below.

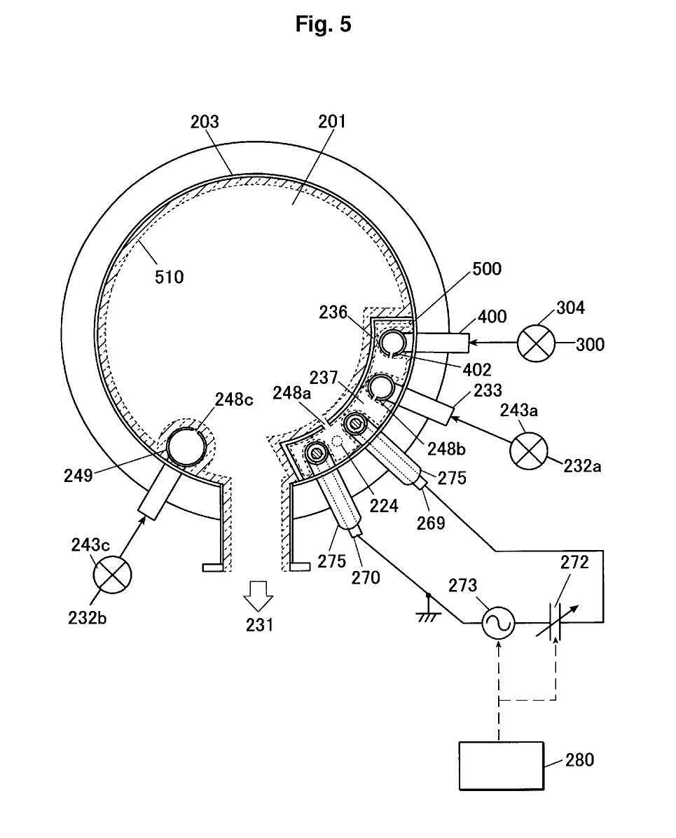

In addition to the nozzle 233 of FIG. 3, as shown in FIG. 5, a nozzle 400 is installed in the buffer chamber 237. The gas supply pipe 300 is connected to the nozzle 400. The nozzle 400 extends from the downside to the upside of the reaction tube 203 in the up-and-down direction of FIG. 2. At the nozzle 400, gas supply holes 402 are formed in the same manner as the gas supply holes 248b.

In a coating process, when DCS gas is supplied to the buffer chamber 237, the DCS gas is introduced from the gas supply pipe 300 into the nozzle 400 and is injected into the buffer chamber 237 through the gas supply holes 402 of the nozzle 400.

In the above-described embodiment, since DCS gas can be directly supplied to the buffer chamber 237, a part of the reaction tube 203 constituting the buffer chamber 237 can be coated with a Si₃N₄ film 500, and thus contaminants can be prevented or restrained from penetrating through the reaction tube 203 and contaminating the wafer 200.

### Third Embodiment

The third embodiment is the same as the first embodiment in all aspects, except for those described below.

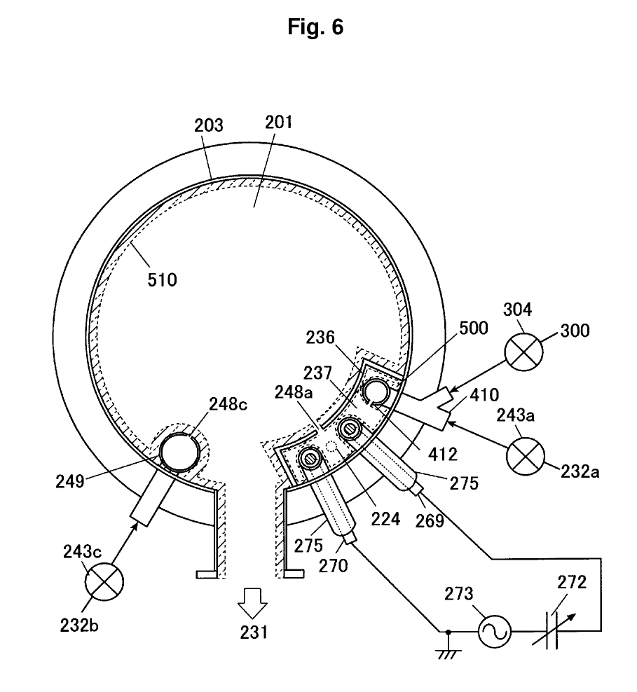

Instead of the nozzle 233 of FIG. 3, as shown in FIG. 6, a nozzle 410 is installed in the buffer chamber 237. At the outside of the reaction tube 203, the nozzle 410 is divided into two parts: one is connected to the gas supply pipe 232a, and the other is connected to the gas supply pipe 300. The nozzle 410 extends from the downside to the upside of the reaction tube 203 in the up-and-down direction of FIG. 2, and gas supply holes 412 are formed in the nozzle 410 in the same manner as the gas supply holes 248b.

In a coating process, when NH₃ gas is supplied to the buffer chamber 237, the NH₃ gas is introduced from the gas supply pipe 232a into the nozzle 410 and is injected into the buffer chamber 237 through the gas supply holes 412 of the nozzle 410. DCS gas is supplied to the buffer chamber 237 as follows: DCS gas is introduced from the gas supply pipe 300 to the nozzle 410 and is injected into the buffer chamber 237 through the gas supply holes 412 of the nozzle 410.

In the steps 1 to 4 of the film forming process, NH₃ gas is supplied to the buffer chamber 237 as follows: NH₃ gas is introduced from the gas supply pipe 232a to the nozzle 410 and is injected into the buffer chamber 237 through the gas supply holes 412 of the nozzle 410.

In the above-described embodiment, since DCS gas can be directly supplied to the buffer chamber 237, a part of the reaction tube 203 constituting the buffer chamber 237 can be coated with a Si₃N₄ film 500, and thus it can be prevented or suppressed that contaminants penetrate into the reaction tube 203 and contaminate the wafer 200.

In the first to third embodiments, the coating process is performed using an ALD method by alternately supplying NH₃ gas and DCS gas to the buffer chamber 237, in order to coat the inside of the buffer chamber 237 with the Si₃N₄ film 500. However, particularly in the second and third embodiments, NH₃ gas and DCS gas may be simultaneously supplied to the buffer chamber 237 by a CVD method to coat the inside of the buffer chamber 237 with a Si₃N₄ film 500.

On the other hand, in the first embodiment, the inside of the buffer chamber 237 may be coated with the Si₃N₄ film 500 by employing only the ALD method in which NH₃ gas and DCS gas are alternately supplied to the buffer chamber 237, and generally, it may not be preferable that the inside of the buffer chamber 237 be coated with the Si₃N₄ film 500 by employing the CVD method in which NH₃ gas and DCS gas are simultaneously supplied to the buffer chamber 237.

Coating by the CVD method is not preferable due to the following reason. If NH₃ gas and DCS gas are mixed, NHCl is generated at a temperature equal to or lower than 300° C., and the NHCl attaches to the gas supply pipes 232a and 300 (particularly, to the periphery of the junction of the gas supply pipe 232a and the gas supply pipe 300) as a byproduct. Although the generation of the byproduct can be prevented by maintaining the temperature at 300° C. or higher, it is practically difficult to heat the gas supply pipes 232a and 300 to a temperature of 300° C. or higher. Therefore, in the first embodiment, it is preferable to use the ALD method for coating the inside of the buffer chamber 237 with the Si₃N₄ film 500.

In addition, although the inside of the buffer chamber 237 can be coated using the CVD method in the second and third embodiments, it is preferable to coat the inside of the reaction tube 203 including the buffer chamber 237 using the ALD method in the first to third embodiments.

As shown in Table 1 below, although the processing time is about 300 minutes in coating by the ALD method, the processing time reduces to about 10 minutes in coating by the CVD method. Thus, it is considered that coating by the CVD method brings a better throughput.

TABLE 1

| Film-forming | Film-forming | Number of | Processing Time |
|---|---|---|---|
| Method | Temperature [° C.] | Cycles | [Minute] |
| ALD | ~600 | ~150 | ~300 |
| CVD | ~780 | 1 | ~10 |

When temperatures for coating by the ALD method and coating by the CVD method are compared, although the coating by the ALD method is performed at about 600° C., the coating by the CVD method is performed at a higher temperature of about 780° C. That is, the CVD method requires a high-temperature processing. However, when considering the heat-resistant temperature of members (e.g., the seal cap 219) constituting the lower portion of the processing chamber 201, the temperature limit of the reaction tube 203 is about 650° C. Therefore, in the coating by the CVD method, processing at that temperature is difficult, and thus, it is preferable to perform coating by the ALD method in the first to third embodiments.

In an ordinary film forming process comprised of the steps 1 to 4, the processing temperature is 450° C. to 550° C. However, as shown in Table 1, in the coating process using the ALD method, the processing temperature is high at about 600° C. because plasma is not generated in the buffer chamber 237.

[Experiment 1]

In the experiment 1, the same substrate processing apparatus as that illustrated in FIG. 1, FIG. 2, and FIG. 3 was used, and Na concentrations were measured from the same sides of wafers.

In detail, since it is difficult to measure Na concentrations from regions of the same side of a wafer, Na concentrations of the same side of a wafer were predicted in the following procedures.

Two small-diameter wafers (200-mm diameter wafers) were placed at the upside of a large-diameter wafer (300-mm diameter wafer). One of the two small-diameter wafers was placed at a position close to and facing a buffer chamber, and the other was placed at a position most distant from the buffer chamber (opposite to the buffer chamber). In this state, the wafers were charged into a boat and set to a processing furnace.

Thereafter, while operating a heater without operating a boat rotating mechanism (without rotating the wafers), NH₃ gas and DCS gas were alternately supplied to a processing chamber through gas supply pipes, and Si₃N₄ films were formed on the two 200-mm diameter wafers. Then, by using an inductively coupled plasma mass spectrometry (ICP-MS) instrument, Na concentrations of the two small-diameter wafers were measured. The measured results are shown in Table 2 below.

TABLE 2

| Position | Na Concentration [atoms/cm²] |
|---|---|
| Buffer chamber side | 1.25 × 10¹¹ |
| Side opposite to buffer chamber | 6.10 × 10¹⁰ |

In table 2, the Na concentration of the buffer chamber side is a Na concentration measured from the closely-positioned small-diameter wafer, which is predicted as the Na concentration at a side edge portion of the large-diameter wafer facing the buffer chamber, and the Na concentration at side opposite to the buffer chamber is a measured Na concentration of the distantly-positioned small-diameter wafer, which is predicted as the Na concentration of another side edge portion of the large-diameter wafer that is angled 180° away from the formerly-mentioned side edge portion about the center of the large-diameter wafer.

As shown in Table 2, comparing the buffer chamber side and the side opposite to the buffer chamber, the buffer chamber side has a higher Na concentration of 1.25×10¹¹ atoms/cm², and it is thought that Na penetrates the buffer chamber through a wall of a reaction tube constituting the buffer chamber.

[Experiment 2]

In the experiment 2, the same substrate processing apparatus as that illustrated in FIG. 1, FIG. 2, and FIG. 3 was used, and Na concentrations were measured for the case where the inside of a buffer chamber is not coated and the case where the inside of the buffer chamber is coated.

(1) The Case where the Inside of Buffer Chamber is not Coated

One hundred of wafers were charged into a boat and set to a processing furnace. Then, while operating a heater, NH₃ gas and DCS gas are alternately supplied to a processing chamber through gas supply pipes to form Si₃N₄ films on the wafers. Thereafter, by using an ICP-MS instrument, Na concentrations (mean values) of the wafers were measured according to charged positions of the wafers in the boat (in the following description, the charged positions of the wafers in the boat are grouped into the three categories of top, center, and bottom positions, and are denoted as such). The measurement results are shown in Table 3 below.

(2) The Case where the Inside of Buffer Chamber is Coated

One hundred of wafers were charged into the boat and set to the processing furnace. Then, while operating the heater, NH₃ gas and DCS gas are alternately supplied to the processing chamber through the gas supply pipes to form Si₃N₄ films on the wafers. Thereafter, by using the ICP-MS instrument, Na concentrations (mean values) of the wafers were measured according to the charged positions (top, center, and bottom positions) of the wafers in the boat. The measurement results are shown in Table 3 below.

TABLE 3

| | |
|---|---|
| Existence of | Na Concentration [atoms/cm²] |

| Coating | Top | Center | Bottom |
|---|---|---|---|
| Poly Si coat | 2.79 × 10¹¹ | 2.30 × 10¹¹ | 3.38 × 10¹¹ |
| (Not present) | | | |
| Poly Si coat | 1.61 × 10¹¹ | 1.50 × 10¹¹ | 3.08 × 10¹¹ |
| (Present) | | | |

As shown in Table 3, when comparing cases where the buffer chamber is and is not coated with a poly-Si film, the presence of the poly-Si film produces somewhat of a coating effect on the buffer chamber. However, even when coating is performed, the Na concentration reduction target, that is, a Na concentration of 1×10¹° atoms/cm² or less, is not achieved on any of the wafers at the top, center, and bottom positions. Therefore, it is assumed that since there are relatively large gaps between grains of poly-Si film, Na ions move through the gaps.

[Experiment 3]

In the experiment 3, the same substrate processing apparatus as that illustrated in FIG. 1, FIG. 2 and FIG. 3 was used; the inside of a buffer chamber was coated by a CVD method or an ALD method; and Na concentrations were measured according to the film forming methods.

(1) Coating by CVD Method

One hundred of wafers were charged into a boat and set to a processing furnace. Thereafter, a heater was operated in a state where plasma was not generated, and NH₃ gas and DCS gas were simultaneously supplied to the buffer chamber through gas supply pipes, so as to coat the inside of the buffer chamber with a Si₃N₄ film. Then, while operating the heater, NH₃ gas and DCS gas were alternately supplied to a processing chamber through gas supply pipes, and as a result, Si₃N₄ films were formed on the wafers. After that, by using an ICP-MS instrument, Na concentrations (mean values) of the wafers were measured according to the charged positions (top, center, and bottom positions) of the wafers in the boat. The measurement results are shown in Table 4 below.

(2) Coating by ALD Method

One hundred of wafers were charged into the boat and set to the processing furnace. Thereafter, the heater was operated in a state where plasma was not generated, and NH₃ gas and DCS gas were alternately supplied to the buffer chamber through the gas supply pipes, so as to coat the inside of the buffer chamber with a Si₃N₄ film. Then, while operating the heater, NH₃ gas and DCS gas were alternately supplied to the processing chamber through the gas supply pipes, and as a result, Si₃N₄ films were formed on the wafers. After that, by using the ICP-MS instrument, Na concentrations (mean values) of the wafers were measured according to the charged positions (top, center, and bottom positions) of the wafers in the boat. The measurement results are shown in Table 4 below. In Table 4, values in the case where a Si₃N₄ film is not formed on the inside of the buffer chamber are also given.

TABLE 4

| | |
|---|---|
| Existence of | Na Concentration [atoms/cm²] |

| Coating | Top | Center | Bottom |
|---|---|---|---|
| No coat | 1.20 × 10¹¹ | 1.00 × 10¹¹ | 2.00 × 10¹¹ |
| CVD coat | 3.30 × 10⁹ | 9.20 × 10⁹ | 4.40 × 10¹⁰ |
| ALD coat | <1 × 10⁷ | <1 × 10⁷ | 1.50 × 10⁹ |

As shown in Table 4, in the case where the buffer chamber is coated by the CVD method, the target Na concentration value, equal to or lower than 1×10¹⁰ atoms/cm², is achieved on the wafers at the top and center positions; however, the target Na concentration value is not achieved on the wafers of the bottom position. The reason for this is that although the temperatures at the top and center positions reach about 780° C., the temperature at the bottom position reaches only about 600° C., and thus a coating film thickness of 150 Å cannot be obtained at the bottom position.

On the contrary, in the case where the buffer chamber is coated by the ALD method, the target Na concentration, equal to or lower than 1×10¹⁰ atoms/cm², is achieved on any wafer at the top, center and center positions. From the above, it is thought that coating of the buffer chamber with the ALD method is the better way of reducing Na concentration.

According to a first substrate processing apparatus relevant to an aspect of the present invention, when a predetermined part of the reaction tube is coated with a film, second and third processing gases are supplied to a plasma generating space so that at least a part of the reaction tube constituting the plasma generating space can be coated with a film. Therefore, although plasma is generated in the plasma generating space when a film is actually formed on a substrate, penetration of a wafer contaminant through the part of the reaction tube constituting the plasma generating space can be prevented. Accordingly, contaminants can be prevented or restrained from penetrating through the reaction tube and contaminating a substrate.

According to a second substrate processing apparatus relevant to another aspect of the present invention, to form a film on a substrate and to coat a part of the reaction tube near the electrodes with a film, the heating temperature of the heater is set to different values. For example, the heating temperature for coating the reaction tube is set higher than the heating temperature for forming a film on a substrate, such that although plasma is not generated in the reaction tube, the part of the reaction tube near the electrodes can be coated with a film. Therefore, although plasma is generated in the reaction tube when a film is actually formed on a substrate, penetration of a wafer contaminant through the part of the reaction tube near the electrodes can be prevented. Accordingly, contaminants can be prevented or restrained from penetrating through the reaction tube and contaminating a substrate.

According to a third substrate processing apparatus relevant to another aspect of the present invention, when a part of the reaction tube near the electrodes is coated with a film, high-frequency power is not supplied to the electrodes so that penetration of a wafer contaminant through the part of the reaction tube near the electrodes can be suppressed during the coating process. Furthermore, for example, if the heating temperature of the heat is set to a high temperature, the part of the reaction tube near the electrodes can be coated with a film although plasma is not generated in the reaction tube. Thus, although plasma is generated in the reaction tube by high-frequency power supplied to the electrodes when a film is actually formed on a substrate, penetration of a wafer contaminant through the part of the reaction tube near the electrodes can be prevented. Accordingly, contaminants can be prevented or restrained from penetrating through the reaction tube and contaminating a substrate.

According to a coating method relevant to another aspect of the present invention, since first and second processing gases are supplied to a plasma generating space, at least a part of the reaction tube constituting the plasma generating space can be coated with a film. Therefore, although plasma is generated in the plasma generating space when a film is actually formed on a substrate, penetration of a wafer contaminant through the part of the reaction tube constituting the plasma generating space can be prevented. Accordingly, contaminants can be prevented or restrained from penetrating through the reaction tube and contaminating a substrate.

While preferred aspects and embodiments of the present invention have been described, the present invention also includes the following embodiments.

(Supplementary Note 1)

According to a preferred embodiment of the present invention, there is provided a substrate processing apparatus including: a reaction tube configured to accommodate a substrate and including an inner space divided into a film forming space where a desired film is formed on the substrate and a plasma generating space where plasma is generated; a gas supply unit configured to supply a desired processing gas into the reaction tube; at least a pair of electrodes connected to a high-frequency power supply unit and disposed at the plasma generating space; an exhaust unit configured to exhaust an inside atmosphere of the reaction tube; and a controller configured to control at least the gas supply unit, wherein the gas supply unit includes: a first gas supply line configured to supply a first processing gas to the film forming space; a second gas supply line configured to supply a second processing gas to the plasma generating space; and a third gas supply line configured to supply the plasma generating space with a third processing gas which is the same kind of gas as the first processing gas, wherein the controller controls the gas supply unit so that at least the first and second processing gases are supplied when a desired film is formed on the substrate accommodated in the reaction tube; and the controller controls the gas supply unit so that at least the second and third processing gases are supplied when at least a part of the reaction tube constituting the plasma generating space is coated with a desired film.

The first processing gas is gas including a first element (for example, Si). The second processing gas is gas including a second element (for example, N). The third processing gas is the same kind of gas as the first processing gas, and specifically, the third processing gas includes the first element (for example, Si). That is, regardless of the fact that the first and third processing gases have the same or different element compositions, the first and third processing gases are the same kind of gas as long as they have the first element (a common element).

(Supplementary Note 2)

In the substrate processing apparatus of Supplementary Note 1, it is preferable that the second gas supply line include a first nozzle configured to supply the second processing gas to the plasma generating space, and the third gas supply line include a second nozzle configured to supply the third processing gas to the plasma generating space.

(Supplementary Note 3)

In the substrate processing apparatus of Supplementary Note 1, it is preferable that the substrate processing apparatus further include a nozzle disposed at the plasma generating space, wherein the second and third gas supply lines include the nozzle as a common member, and the second and third processing gases are supplied to the plasma generating space through the nozzle.

(Supplementary Note 4)

In the substrate processing apparatus of Supplementary Note 1, it is preferable that when at least the part of the reaction tube constituting the plasma generating space is coated with the desired film, the controller control the gas supply unit so that the second and third processing gases are alternately supplied.

(Supplementary Note 5)

In the substrate processing apparatus of Supplementary Note 1, it is preferable that at least the part of the reaction tube constituting the plasma generating space be coated with a film having a molecular distance smaller than a radius of Na ions.

(Supplementary Note 6)

In the substrate processing apparatus of Supplementary Note 1, it is preferable that when the desired film is formed on the substrate accommodated in the reaction tube, the controller control the high-frequency power supply unit so as to supply high-frequency power to the electrodes; and when at least the part of the reaction tube constituting the plasma generating space is coated with the desired film, the controller control the high-frequency power supply unit so as not to supply high-frequency power to the electrodes.

(Supplementary Note 7)

In the substrate processing apparatus of Supplementary Note 1 or 6, it is preferable that when the desired film is formed on the substrate accommodated in the reaction tube, the controller control a heater so as to set a heating temperature of the heater to a first temperature; and when at least the part of the reaction tube constituting the plasma generating space is coated with the desired film, the controller control the heater so as to set the heating temperature of the heater to a second temperature higher than the first temperature.

(Supplementary Note 8)

In the substrate processing apparatus of Supplementary Note 7, it is preferable that the first temperature range from about 450° C. to about 550° C., and the second temperature range from about 580° C. to about 630° C.

(Supplementary Note 9)

In the substrate processing apparatus of Supplementary Note 1, it is preferable that when about 50 W of high-frequency power be supplied to the electrodes, at least the part of the reaction tube constituting the plasma generating space be coated with a film having a thickness equal to or greater than about 150 Å.

(Supplementary Note 10)

According to another preferred embodiment of the present invention, there is provided a substrate processing apparatus including: a reaction tube configured to accommodate a substrate; a heater configured to heat the substrate accommodated in the reaction tube; a first gas supply line configured to supply a first processing gas to an inside of the reaction tube; a second gas supply line configured to supply a second processing gas to the inside of the reaction tube; at least a pair of electrodes connected to a high-frequency power supply unit and configured to excite the second processing gas supplied to the inside of the reaction tube into a plasma state; an exhaust unit configured to exhaust an inside atmosphere of the reaction tube; and a controller configured to control at least the heater, the first gas supply line, and the second gas supply line, wherein when a desired film is formed on the substrate accommodated in the reaction tube and when at least a part of the reaction tube near the electrodes is coated with a desired film, the controller controls the first and second gas supply lines so that the first and second processing gases are supplied; and when the desired film is formed on the substrate accommodated in the reaction tube and when at least a part of the reaction tube near the electrodes is coated with a desired film, the controller controls the heater so as to set a heating temperature of the heater to different values.

(Supplementary Note 11)

In the substrate processing apparatus of Supplementary Note 10, it is preferable that when the desired film is formed on the substrate accommodated in the reaction tube, the controller control the high-frequency power supply unit so as to supply high-frequency power to the electrodes, and when at least the part of the reaction tube near the electrodes is coated with the desired film, the controller control the high-frequency power supply unit so as not to supply high-frequency power to the electrodes.

(Supplementary Note 12)

According to another preferred embodiment of the present invention, there is provided a substrate processing apparatus including: a reaction tube configured to accommodate a substrate; a heater configured to heat the substrate accommodated in the reaction tube; a first gas supply line configured to supply a first processing gas to an inside of the reaction tube; a second gas supply line configured to supply a second processing gas to the inside of the reaction tube; at least a pair of electrodes connected to a high-frequency power supply unit and configured to excite the second processing gas supplied to the inside of the reaction tube into a plasma state; an exhaust unit configured to exhaust an inside atmosphere of the reaction tube; and a controller configured to control at least the first gas supply line, the second gas supply line, and the high-frequency power supply unit, wherein when a desired film is formed on the substrate accommodated in the reaction tube and when at least a part of the reaction tube near the electrodes is coated with a desired film, the controller controls the first and second gas supply lines so that the first and second processing gases are supplied; and when the desired film is formed on the substrate accommodated in the reaction tube, the controller controls the high-frequency power supply unit so as to supply high-frequency power to the electrodes, and when at least the part of the reaction tube near the electrodes is coated with the desired film, the controller controls the high-frequency power supply unit so as not to supply high-frequency power to the electrodes.

(Supplementary Note 13)

In the substrate processing apparatus of Supplementary Note 12, it is preferable that when the desired film is formed on the substrate accommodated in the reaction tube, the controller control the heater so as to set a heating temperature of the heater to a first temperature, and when at least the part of the reaction tube near the electrodes is coated with the desired film, the controller control the heater so as to set the heating temperature of the heater to a second temperature higher than the first temperature.

(Supplementary Note 14)

In the substrate processing apparatus of Supplementary Note 13, it is preferable that the first temperature range from about 450° C. to about 550° C., and the second temperature range from about 580° C. to about 630° C.

(Supplementary Note 15)

According to another preferred embodiment of the present invention, in a substrate processing apparatus including: a reaction tube configured to accommodate a substrate and including an inner space divided into a film forming space where a desired film is formed on the substrate and a plasma generating space where plasma is generated; a gas supply unit configured to supply a desired processing gas into the reaction tube; at least a pair of electrodes connected to a high-frequency power supply unit and disposed at the plasma generating space; and an exhaust unit configured to exhaust an inside atmosphere of the reaction tube, a coating method is provided for coating at least a part of the reaction tube constituting the plasma generating space with a desired film, the coating method including: supplying a first processing gas to the plasma generating space; exhausting the inside atmosphere of the reaction tube; supplying a second processing gas to the plasma generating space; and exhausting the inside atmosphere of the reaction tube.

(Supplementary Note 16)

In the coating method of Supplementary Note 15, it is preferable that in supplying the first processing gas and supplying the second processing gas, high-frequency power be not supplied to the electrodes, and the first and second process gases be not plasma-excited.

What is claimed is:

1. A coating method for coating a reaction tube having a film forming space where a desired film is formed on a substrate accommodated therein and a plasma generating space where a plasma is generated, the coating method comprising:
supplying a first processing gas into the plasma generating space and exhausting at least a portion of the first processing gas from the plasma generating space without loading the substrate into the film forming space; and
supplying a second processing gas into the plasma generating space to coat at least the plasma generating space with the desired film and exhausting at least a portion of the second processing gas from the plasma generating space without loading the substrate into the film forming space.

2. The coating method of claim 1, wherein at least one electrode connected to a high-frequency power supply unit is disposed in the plasma generating space, and
wherein the first processing gas and the second processing gas are supplied without supplying a high frequency power to the at least one electrode.

3. The coating method of claim 1, wherein an inside temperature of the reaction tube when the plasma generating space is coated with the desired film is higher than that of the reaction tube when the desired film is formed on the substrate in the film forming space.

4. The coating method of claim 1, wherein at least one electrode connected to a high-frequency power supply unit is disposed in the plasma generating space, and
wherein the desired film is formed on the substrate in the film forming space after coating the at least the plasma generating space with the desired film.

5. A coating method performed in a substrate processing apparatus comprising a reaction tube having a film forming space where a desired film is formed on a substrate accommodated therein and a plasma generating space where a plasma is generated; a gas supply unit configured to supply a first processing gas and a second processing gas into the reaction tube; at least one electrode disposed in the plasma generating space and connected to a high-frequency power supply unit; and an exhaust unit configured to exhaust an inside atmosphere of the reaction tube, the coating method comprising:
supplying the first processing gas into the plasma generating space by the gas supply unit without loading the substrate into the film forming space;
exhausting the inside atmosphere of the reaction tube by the exhaust unit;
supplying the second processing gas into the plasma generating space by the gas supply unit without loading the substrate into the film forming space; and
exhausting the inside atmosphere of the reaction tube by the exhaust unit,
wherein at least the plasma generating space of the reaction tube is coated with the desired film.

6. The coating method of claim 5, wherein the first processing gas and the second processing gas are supplied without supplying a high frequency power to the at least one electrode.

7. A method for manufacturing a semiconductor device using a reaction tube coating having a film forming space where a desired film is formed on a substrate accommodated therein and a plasma generating space where a plasma is generated, the coating method comprising:
supplying a first processing gas into the plasma generating space and exhausting at least a portion of the first processing gas from the plasma generating space without loading the substrate into the film forming space;
supplying a second processing gas into the plasma generating space to coat at least the plasma generating space with the desired film and exhausting at least a portion of the second processing gas from the plasma generating space without loading the substrate into the film forming space; and
forming the desired film is on the substrate in the film forming space with the substrate loaded therein after coating the at least the plasma generating space with the desired film.
